(19) United States
(12) Patent Application Publication
(10) Pub. No.: US 2020/0251684 A1
(43) Pub. Date: Aug. 6, 2020

(54) LIGHT-EMITTING DEVICE

(71) Applicant: PIONEER CORPORATION, Bunkyo-ku, Tokyo (JP)

(72) Inventor: Takeru OKADA, Bunkyo-ku, Tokyo (JP)

(21) Appl. No.: 16/492,556

(22) PCT Filed: Feb. 28, 2018
(86) PCT No.: PCT/JP2018/007572

§ 371 Date: Sep. 9, 2019

(30) Foreign Application Priority Data
Mar. 9, 2017 (JP) 2017-045094

(51) Int. Cl. H01L 51/52; H05B 33/04; H01L 51/50; H05B 33/26

(52) U.S. Cl. CPC H01L 51/5253; H05B 33/04; H01L 2251/301; H01L 51/5246; H05B 33/26; H01L 51/5012

(57) ABSTRACT

A light-emitting unit (140) is located on a first surface (100a) side of a substrate (100). At least a portion of an organic layer is located between the light-emitting unit (140) and an end (100c) of the substrate (100). In the example shown in FIG. 1, this organic layer is an organic insulating film (150) . Below, a description will be given with the organic layer as the organic insulating film (150). However, this organic layer maybe an organic layer (120) which will be described later. A first covering layer (200) covers the light-emitting unit (140) and the organic insulating film (150). An intermediate layer (300) is in contact with a surface of the first covering layer (200) on the opposite side of the substrate (100), and at least a portion of the intermediate layer is located more to the end (100c) side than the organic insulating film (150). In addition, the intermediate layer (300) includes a desiccant. A second covering layer (400) is in contact with a surface of the intermediate layer (300) on the opposite side of the substrate (100).

### TECHNICAL FIELD

The present invention relates to a light-emitting device.

### BACKGROUND ART

One of light-emitting devices such as illumination, a display, or the like is a device using an organic EL. Since an organic material is used in a light-emitting layer in the organic EL, in order to provide the organic EL with durability, it is necessary to seal a light-emitting unit.

Patent Document 1 discloses covering an organic layer with a laminated structure including a sealing layer, a hygroscopic layer, and a protection layer. The sealing layer includes a thermoplastic resin. The protection layer is a metal foil or a laminated body including a plastic film and an inorganic compound layer.

Patent Document 2 discloses covering an organic layer with a sealing layer formed by ALD. As the sealing layer, for example, ALOₓ is disclosed.

### RELATED ART DOCUMENT

### Patent Documents

[Patent Document 1]: WO/2013/021924
[Patent Document 2]: Japanese Unexamined Patent Application Publication No. 2016-62764

### SUMMARY OF THE INVENTION

In order to sufficiently seal an organic layer, the inventor of the present invention considered forming a first covering layer on a light-emitting unit, providing an intermediate layer including a desiccant on the first covering layer, and in addition, covering the first covering layer and the intermediate layer with a second covering layer. However, it became clear that even when such a structure is adopted, depending on the location of the intermediate layer, moisture or the like outside the light-emitting device may reach the light-emitting unit.

An example of the problem to be solved by the present invention is to prevent moisture or the like outside a light-emitting device from easily reaching a light-emitting unit when a first covering layer is formed on a light unit, an intermediate layer including a desiccant is provided on the first covering layer, and in addition, the first covering layer and the intermediate layer are covered with a second covering layer.

### Means for Solving the Problem

The invention described in claim 1 is a light-emitting device including:

a light-emitting unit located on a first surface side of a substrate;

an organic layer having at least a portion thereof located between the light-emitting unit and an end of the substrate;

a first covering layer covering the light-emitting unit and the organic layer;

an intermediate layer including a desiccant, the intermediate layer being in contact with a surface of the first covering layer on an opposite side of the substrate and having at least a portion thereof located more to the end side than the organic layer; and

a second covering layer in contact with a surface of the intermediate layer on an opposite side of the substrate.

### BRIEF DESCRIPTION OF THE DRAWINGS

The objects described above, and other objects, features and advantages are further made apparent by suitable embodiments that will be described below and the following accompanying drawings.

FIG. 1 is cross-sectional view showing a configuration of a light-emitting device according to an embodiment.

FIG. 2 is a cross-sectional view showing a configuration of a light-emitting device according to a comparative example.

FIG. 3 is a cross-sectional view showing a configuration of a light-emitting device according to a first modification example.

FIG. 4 is a cross-sectional view showing a configuration of a light-emitting device according to a second modification example.

FIG. 5 is a cross-sectional view showing a configuration of a light-emitting device according to a third modification example.

### DESCRIPTION OF EMBODIMENT

Embodiments of the present invention will be described below by referring to the drawings. Moreover, in all the drawings, the same constituent elements are given the same reference numerals, and descriptions thereof will not be repeated.

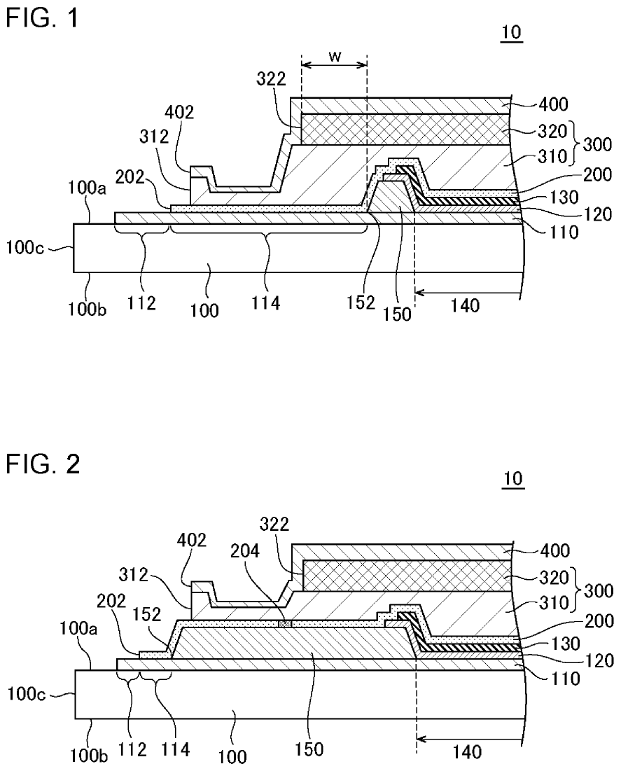

FIG. 1 is a cross-sectional view showing a configuration of a light-emitting device 10 according to an embodiment. The light-emitting device 10 according to the embodiment is a lighting device, an illumination device, or a display, and includes a light-emitting unit 140, an organic layer, a first covering layer 200, an intermediate layer 300, and a second covering layer 400. The light-emitting unit 140 is located on a first surface 100a side of a substrate 100. At least a portion of the organic layer is located between the light-emitting unit 140 and an end 100c of the substrate 100. In the example shown in FIG. 1, this organic layer is an organic insulating film 150. Below, a description will be given with the organic layer as the organic insulating film 150. However, this organic layer may be an organic layer 120 which will be described later. The first covering layer 200 covers the light-emitting unit 140 and the organic insulating film 150. The intermediate layer 300 is in contact with a surface of the first covering layer 200 on the opposite side of the substrate 100, and at least a portion thereof is located more to the end 100c side than the organic insulating film 150. In addition, the intermediate layer 300 includes a desiccant. The second covering layer 400 is in contact with a surface of the intermediate layer 300 on the opposite side of the substrate 100. The light-emitting device 10 will be described in detail below.

The light-emitting device 10 includes the light-emitting unit 140 as described above. The light-emitting unit 140 is formed using the substrate 100. The light-emitting unit 140 is, for example, a bottom-emission type, and emits light from a second surface 100b side of the substrate 100. However, the light-emitting unit 140 may be a top-emission type or a both-sided light emission type. In addition, the light-emitting device 10 may have a plurality of light-emitting units 140. In this case, the light-emitting device 10 may include a region (light-transmitting portion) which transmits visible light between the plurality of light-emitting units 140.

The substrate 100 is formed of a light-transmitting material, for example, glass, a light-transmitting resin, or the like. The shape of a substrate is polygonal such as, for example, rectangular or the like. The substrate 100 may have flexibility. In a case where the substrate 100 has flexibility, the thickness of the substrate 100 is, for example, equal to or greater than 10 pm and equal to or less than 1,000 pm. In a case of providing the substrate 100 including glass in particular with flexibility, the thickness of the substrate 100 is, for example, equal to or less than 200 μm. In a case of providing the substrate 100 formed of a resin material with flexibility, a material of the substrate 100 is, for example, at least one of polyethylene naphthalate (PEN), polyether sulphone (PES), polyethylene terephthalate (PET), and polyimide. Meanwhile, in a case where the substrate 100 is formed of a resin material, an inorganic barrier film of SiNₓ, SiON or the like is preferably formed on at least the light-emitting surface (preferably on both surfaces) of the substrate 100 in order to prevent moisture from passing through the substrate 100.

Meanwhile, in a case where the light-emitting unit 140 is a top-emission type, the substrate 100 need not be light-transmitting.

The light-emitting unit 140 is formed on the first surface 100a of the substrate 100 as described above, and includes a first electrode 110, the organic layer 120, and a second electrode 130. A case where the light-emitting unit 140 is a bottom-emission type will be described in detail below.

The first electrode 110 is formed of a transparent conductive film. This transparent conductive film is a material containing a metal, for example, a metal oxide formed of an indium tin oxide (ITO), an indium zinc oxide (IZO), an indium tungsten zinc oxide (IWZO), a zinc oxide (Zn0), or the like. The refractive index of the material of the transparent electrode is, for example, equal to or greater than 1.5 and equal to or less than 2.2. The thickness of the transparent electrode is, for example, equal to or greater than 10 nm and equal to or less than 500 nm. The transparent electrode is formed by, for example, sputtering or vapor deposition. Meanwhile, the transparent electrode may be a conductive organic material such as carbon nanotubes or PEDOT/PSS, or a thin metal electrode.

The organic layer 120 is located between the first electrode 110 and the second electrode 130, and includes a hole injection layer, a hole transport layer, a light-emitting layer, an electron transport layer, and an electron injection layer. However, either of the hole injection layer and the hole transport layer need not be formed. In addition, either of the electron transport layer and the electron injection layer need not be formed. The organic layer 120 may further include other layers. The organic layer 120 is formed using, for example, vapor deposition, but at least a portion of the layers may be formed using a coating method. The organic layer 120 is continuously formed on each of the organic insulating film 150 to be described later and the region of the first electrode 110 to serve as the light-emitting unit 140.

The second electrode 130 includes, for example, a metal layer, and does not have light-transmitting properties. A metal layer included in the second electrode 130 is, for example, a layer composed of a metal selected from a first group consisting of Al, Au, Ag, Pt, Mg, Sn, Zn, and In, or an alloy of metals selected from the first group.

Further, the organic insulating film 150 is formed on the first electrode 110. The organic insulating film 150 includes an opening in a region of the first electrode 110 to serve as the light-emitting unit 140. In other words, the organic insulating film 150 defines the light-emitting unit 140. The organic insulating film 150 is formed using a material, for example, polyimide or the like mixed with a photosensitive material. The organic insulating film 150 is formed after the first electrode 110 is formed and before the organic layer 120 is formed.

The light-emitting device 10 further includes a first terminal 112 and a first wiring 114. The first terminal 112 is a terminal to connect the first electrode 110 to a drive circuit outside the light-emitting device 10 and is connected to an external wiring such as a flexible printed wiring board or the like. The first wiring 114 connects the first terminal 112 to the first electrode 110. Both the first terminal 112 and the first wiring 114 are formed on the first surface 100a. At least a portion of the first terminal 112 and the first wiring 114 may be integral with the first electrode 110. In this case, at least a portion of the first terminal 112 and the first wiring 114 is a transparent conductive film which is the same as the first electrode 110 and is formed in the same step as that of forming the first electrode 110.

As described above, the light-emitting device 10 includes the first covering layer 200, the intermediate layer 300, and the second covering layer 400. The first covering layer 200 is provided to seal the light-emitting unit 140 and overlaps the light-emitting unit 140. In the example shown in the diagram, the first covering layer 200 is in contact with the second electrode 130 of the light-emitting unit 140 and with the organic insulating film 150 and the first wiring 114.

The first covering layer 200 includes at least one layer (preferably a plurality of layers) composed of an inorganic material (hereinafter described as an inorganic layer). This inorganic material is a metal oxide such as, for example, an aluminum oxide or a titanium oxide. For example, the first covering layer 200 includes a laminated film in which a first layer composed of an aluminum oxide and a second layer composed of a titanium oxide are repeatedly laminated. In this case, the thickness of the laminated film is, for example, equal to or greater than 1 nm and equal to or less than 300 nm. In addition, the first layer and the second layer are formed using, for example, Atomic Layer Deposition (ALD). In this case, the thickness of the first layer and that of the second layer are, for example, equal to or greater than 1 nm and equal to or less than 100 nm. Meanwhile, the above-mentioned inorganic layer may be formed using another film formation method such as, for example, CVD or sputtering. In this case, the inorganic layer is, for example, a SiO₂ layer or a SiN layer. In addition, the film thickness of the inorganic layer is, for example, equal to or greater than 100 nm and equal to or less than 300 nm.

The intermediate layer 300 covers the first covering layer 200, and the second covering layer 400 covers the intermediate layer 300. In the example shown in FIG. 1, the intermediate layer 300 and the second covering layer 400 configure one sheet of film.

Specifically, the intermediate layer 300 includes the adhesive layer 310 and a hygroscopic layer 320. The hygroscopic layer 320 includes a hygroscopic agent, and is provided in a portion of the adhesive layer 310 excluding the entire circumferential edge thereof. The second covering layer 400 is a metal layer such as, for example, an aluminum foil. An end of the second covering layer 400 is in contact with an end of the adhesive layer 310 throughout the entire circumference. In other words, the hygroscopic layer 320 is interposed between the adhesive layer 310 and the second covering layer 400.

In addition, when viewed from a direction perpendicular to the substrate 100, an outer end 152 of the organic insulating film 150 (that is, an end on the end 100c side of the substrate 100) is covered with the hygroscopic layer 320. In other words, an outer end 322 of the hygroscopic layer 320 is closer to the end 100c than the end 152 of the organic insulating film 150. A distance w from the end 322 to the end 152 is, for example, equal to or greater than 500 μm and equal to or less than 5,000 μm, but is not limited to this range. Further, an end 202 of the first covering layer 200 is closer to the end 100c of the substrate 100 than the hygroscopic layer 320 of the hygroscopic layer 320. In other words, the end 322 of the hygroscopic layer 320 is located more to the inner side (that is, the light-emitting unit 140 side) than an outer end 402 of the second covering layer 400 and an outer end 312 of the adhesive layer 310.

In addition, the intermediate layer 300 and the second covering layer 400 are fixed to the substrate 100 side by adhering the adhesive layer 310 to a structure on the substrate 100 side (for example, the first covering layer 200) . When performing the fixing, an edge of the adhesive layer 310 (that is, a portion which is not overlapped with the light-emitting unit 140 or the hygroscopic layer 320) is strongly pressed against the substrate 100 compared to other portions. Therefore, the adhesive layer 310 includes, in a region not overlapped with the hygroscopic layer 320, a portion having a film thickness thinner than that of another region (for example, a region which is overlapped with the hygroscopic layer 320).

Next, a method for manufacturing the light-emitting device 10 is described. First, the first electrode 110 is formed on the substrate 100 using, for example, sputtering and photolithography. At this time, at least a portion of the first terminal 112 and the first wiring 114 is also formed. Then, the organic insulating film 150 including a photosensitive material is formed using photolithography. Thereafter, the organic layer 120 is formed. The second electrode 130 is formed next by, for example, vapor deposition using a mask. The light-emitting unit 140 is thus formed on the substrate 100. Next, the first covering layer 200 is formed on the substrate 100. Then, a film having laminated layers of the intermediate layer 300 and the second covering layer 400 is prepared. Next, this film is attached to the substrate 100 using the adhesive layer 310 of the intermediate layer 300. Thus, the light-emitting device 10 is formed.

FIG. 2 is a cross-sectional view showing a configuration of a light-emitting device 10 according to a comparative example. The light-emitting device 10 according to the present drawing has the same configuration as that of the light-emitting device 10 shown in FIG. 1 except that the end 152 of the organic insulating film 150 is located closer to the end 100c of the substrate 100 than the end 332 of the hygroscopic layer 320.

Since the first covering layer 200 is formed by a film forming process such as ALD or the like, there is a case that the first covering layer 200 includes a flaw 204 (for example, a pinhole allowing permeation of moisture). Meanwhile, the organic insulating film 150 and the adhesive layer 310 transmit moisture although in small amounts. Therefore, when the flaw 204 occurs in a portion of the first covering layer 200 which is overlapped with the organic insulating film 150 and the adhesive layer 310 but is not overlapped with the hygroscopic layer 320, there is a risk of moisture or the like which has entered from the end 312 of the adhesive layer 310 entering the organic insulating film 150 through the flaw 204, and further reaching the organic layer 120 through the organic insulating film 150.

In contrast, in the light-emitting device 10 according to the embodiment, the intermediate layer 300 is located more to the end 100c side of the substrate 100 than the organic insulating film 150. Therefore, there is no portion of the first covering layer 200 which is overlapped with the organic insulating film 150 and the adhesive layer 310 but not overlapped with the hygroscopic layer 320. Therefore, it is possible to inhibit moisture from reaching the organic layer 120 via the above-mentioned route.

In addition, even when the flaw 204 shown in FIG. 2 is formed in the first covering layer 200, there is low possibility of moisture reaching the organic layer 120 when the flaw 204 is located in a portion of the first covering layer 200 other than a portion thereof between the end 152 of the organic insulating film 150 and an end of the second electrode 130. Therefore, the light-emitting unit 140 is sufficiently sealed.

FIRST MODIFICATION EXAMPLE

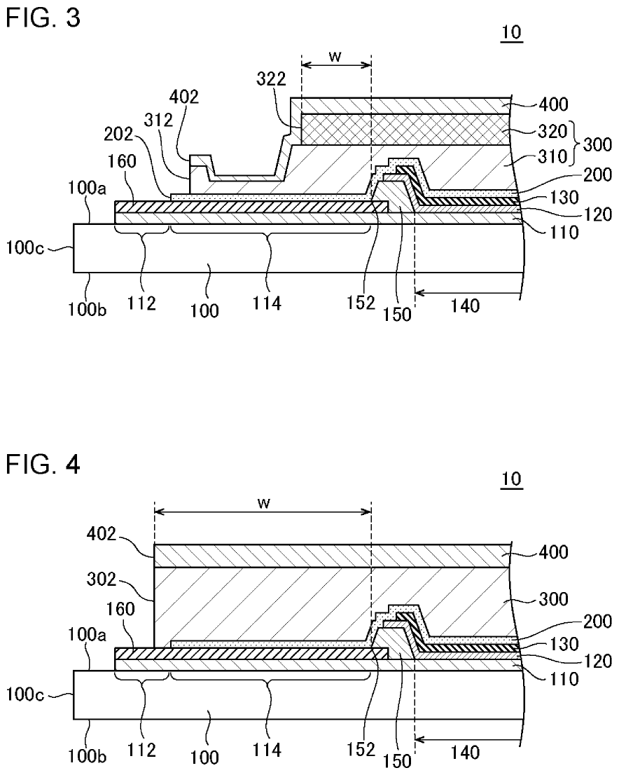

FIG. 3 is a cross-sectional view showing a configuration of a light-emitting device 10 according to the first modification example. The light-emitting device 10 according to the present modification example has the same configuration as that of the light-emitting device 10 according to the embodiment except that the light-emitting device 10 includes a conductive layer 160.

The conductive layer 160 is located between the substrate 100 and the first covering layer 200, specifically, over the first electrode 110, the first terminal 112, and the first wiring 114. The conductive layer 160 functions as an auxiliary electrode of the first electrode 110, and includes, for example, a configuration in which a first metal layer of Mo, a Mo alloy, or the like, a second metal layer of Al, an Al alloy, or the like, and a third metal layer of Mo, a Mo alloy, or the like are laminated in this order. The second metal layer is the thickest of these three layers. The conductive layer 160 extends from the top of the first terminal 112 to the top of the first electrode 110 via the top of the first wiring 114. In other words, one end of the conductive layer 160 is located outside the first covering layer 200.

In the present modification example also, it is possible to prevent moisture from reaching the organic layer 120 via the route described using FIG. 2.

### SECOND MODIFICATION EXAMPLE

FIG. 4 is a cross-sectional view showing a configuration of a light-emitting device 10 according to the second modification example. The light-emitting device 10 according to the present modification example has the same configuration as that of the light-emitting device 10 according to the embodiment except the configuration of the intermediate layer 300 and the second covering layer 400.

In the present modification example, the intermediate layer 300 includes a configuration in which a hygroscopic agent is mixed in the adhesive. Further, the second covering layer 400 is a glass plate, or a resin plate including an inorganic barrier film, or the like. In addition, an end 302 of the intermediate layer 300 is located closer to the end 100c of the substrate 100 than the end 152 of the organic insulating film 150.

In the present modification example also, it is possible to prevent moisture from reaching the organic layer 120 via the route described using FIG. 2.

### THIRD MODIFICATION EXAMPLE

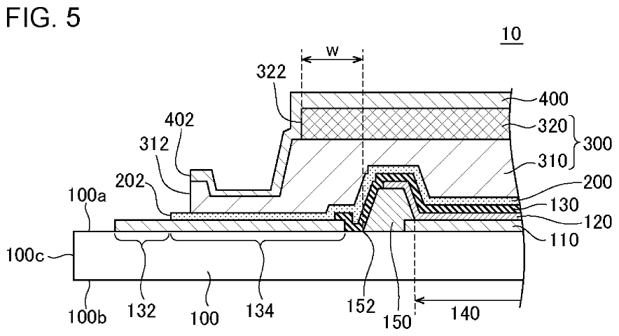

FIG. 5 is a cross-sectional view showing a configuration of a light-emitting device 10 according to the third modification example. The light-emitting device 10 according to the present modification example has the same configuration as that of the light-emitting device 10 according to the embodiment or either of the first modification example and the second modification example except that the light-emitting device 10 includes a second terminal 132 and a second wiring 134 at locations different from those of the first terminal 112 and the first wiring 114.

The second terminal 132 is a terminal to connect the second electrode 130 to a drive circuit outside the light-emitting device 10, and an external wiring such as a flexible printed wiring board or the like is connected thereto. The second wiring 134 (conductive layer) connects the second terminal 132 to the second electrode 130. Both the second terminal 132 and the second wiring 134 are formed between the first surface 100a and the first covering layer 200 (for example, on the first surface 100a) in the thickness direction. At least a portion of the second terminal 132 and the second wiring 134 is a transparent conductive film which is the same as the first electrode 110 or a conductive layer which is the same as the conductive layer 160 shown in FIG. 3.

Further, one end of the second wiring 134 (for example, the second terminal 132) is located outside the first covering layer 200, and the other end of the second wiring 134 is connected to the second electrode 130 between the end 152 of the organic insulating film 150 and the end 322 of the hygroscopic layer 320. Moreover, at least a portion of the second wiring 134 other than both ends thereof is overlapped with the intermediate layer 300. However, the second electrode 130 does not necessarily need to be directly in contact with the other end of the second wiring 134. For example, the second electrode 130 may be connected to the other end of the second wiring 134 through a conductive layer such as a metal layer or the like. In addition, in a case where the other end of the second wiring 134 is overlapped with the organic insulating film 150, the end may be directly connected to the second electrode 130 on the upper surface of the second wiring 134.

According to the present modification example, it is possible to prevent moisture from reaching the organic layer 120 via the route described using FIG. 2.

As described above, although the embodiments and examples of the present invention have been set forth with reference to the accompanying drawings, they are merely illustrative of the present invention, and various configurations other than those stated above can be adopted.

This application claims priority from Japanese Patent Application No. 2017-045094, filed Mar. 9, 2017, the disclosure of which is incorporated by reference in its entirety.

1. A light-emitting device comprising:
a light-emitting unit located on a first surface side of a substrate;
an organic layer having at least a portion thereof located between the light-emitting unit and an end of the substrate;
a first covering layer covering the light-emitting unit and the organic layer;
an intermediate layer comprising a desiccant, the intermediate layer being in contact with a surface of the first covering layer on an opposite side of the substrate and having at least a portion thereof located more to the end side than the organic layer; and
a second covering layer in contact with a surface of the intermediate layer on an opposite side of the substrate.

2. The light-emitting device according to claim 1,
wherein an end of the first covering layer is closer to the end of the substrate than the desiccant of the intermediate layer.

3. The light-emitting device according to claim 1,
wherein the first covering layer comprises an inorganic film.

4. The light-emitting device according to claim 1,
wherein the light-emitting unit comprises a laminated structure comprising a first electrode, an organic EL layer, and a second electrode in this order from the substrate side, and
wherein the organic layer is an organic insulating film that defines the light-emitting unit.

5. The light-emitting device according to claim 4 further comprising a conductive layer located between the substrate and the first covering layer and connected to the first electrode,
wherein at least one end of the conductive layer is located outside the first covering layer.

6. The light-emitting device according to claim 4 further comprising a conductive layer located between the substrate and the first covering layer,
wherein one end of the conductive layer is located outside the first covering layer,
wherein another end of the conductive layer is connected to the second electrode, and
wherein at least a portion of the conductive layer between the two ends of the conductive layer is overlapped with the intermediate layer.

7. The light-emitting device according to claim 1,
wherein the second covering layer is a metal layer,
wherein the intermediate layer comprises a laminated structure comprising an adhesive layer including an adhesive and a hygroscopic layer including the desiccant,
wherein an end of the hygroscopic layer is located more inside than an end of the second covering layer and an end of the adhesive layer, and
wherein the adhesive layer comprises a portion, in a region not overlapped with the hygroscopic layer, having a film thickness that is thinner than the film thickness thereof in a region overlapped with the hygroscopic layer.
